(19) United States
(12) Patent Application Publication
(10) Pub. No.: US 2026/0121398 A1
(43) Pub. Date: Apr. 30, 2026

(54) Leakage Protection Circuit, Electrical Equipment, and Leakage Protection Method

(71) Applicant: Joulwatt Technology Co., Ltd., Hangzhou City (CN)

(72) Inventors: Wanyue HE, Hangzhou (CN); Guoqiang LIU, Hangzhou (CN)

(21) Appl. No.: 19/332,412

(22) Filed: Sep. 18, 2025

(30) Foreign Application Priority Data
Sep. 27, 2024 (CN) 202411371690.1

(51) Int. Cl. H02H 3/32; G01R 31/08; G01R 31/52; H02H 3/05

(52) U.S. Cl. CPC H02H 3/325; G01R 31/088; G01R 31/52; H02H 3/05

(57) ABSTRACT

The present disclosure relates to a field of protection circuit technology, and discloses a leakage protection circuit, an electrical equipment, and a leakage protection method. The leakage protection circuit comprises: a leakage detection switch; a voltage detection unit, configured to detect an input voltage of a power supply to generate a voltage detection signal; a drive unit, configured to determine a type of input voltage of the power supply based on the voltage detection signal; a threshold generation unit, configured to generate a leakage protection threshold based on the type of the input voltage; a leakage protection unit, configured to detect an operation current flowing through the leakage detection switch and control a load to be in an off state if leakage is detected. The present disclosure not only expands the application scenarios, but also ensures the accuracy.

### CROSS-REFERENCE TO RELATED APPLICATIONS

This present disclosure claims priority to a Chinese patent application No. 202411371690.1, filed on Sep. 27, 2024, and entitled “Leakage Protection Circuit, Electrical Equipment, and Leakage Protection Method”, the entire contents of which are incorporated herein by reference, including the specification, claims, drawings and abstract.

### FIELD OF TECHNOLOGY

The present disclosure relates to a field of protection circuit technology, more particularly, to a leakage protection circuit, an electrical equipment, and a leakage protection method.

### BACKGROUND

During the installation of some equipments, partial connection may occur. If a human body accidentally comes contact it at this time, electric shock is easy to occur, affecting safe operation. For example, in the field of lighting, since many lamp holders still retain dual-terminal access interfaces, when the original lamp tube is replaced, dual-terminal input lamp tubes are generally used. In this case, users generally insert one end into the lamp holder first, and then insert the other end. If the user operates improperly, they may come into contact with the conductive part at the end, resulting in electric shock. Therefore, leakage protection is necessary.

In related technologies, a transistor is typically connected to the power input terminal. The presence of leakage is determined by detecting the current flowing through the transistor. In the event of leakage, the load is directly disconnected to achieve leakage protection. However, such leakage protection function is relatively simple and cannot meet the increasingly intelligent demands of electrical equipments, nor can it satisfy users' safety requirements for electrical system.

### SUMMARY OF THE DISCLOSURE

This disclosure provides a leakage protection circuit, an electrical equipment, and a leakage protection method, which solves the technical problem of effectively detecting and protecting against leakage in different electrical equipments. By accurately identifying different types of power supply, it can achieve leakage detection and protection for different electrical equipments, expanding the disclosure scenarios and fully meeting users' needs for safe electricity use.

In order to achieve the above objectives, the main technical solutions in the present disclosure comprise:

In the first aspect, embodiments of the present disclosure provides a leakage protection circuit, wherein comprising: a leakage detection switch, which is set between a power supply and a load; a voltage detection unit, which is configured to detect an input voltage of the power supply to generate a voltage detection signal; a drive unit, which is configured to determine the type of input voltage of the power supply based on the voltage detection signal, and drive the leakage detection switch to operate; a threshold generation unit, which is configured to generate a leakage protection threshold based on the type of input voltage; a leakage protection unit, which is configured to detect the operation current flowing through the leakage detection switch, and control the load to be in an off state if determining that a leakage is occurred based on the leakage protection threshold and the operation current of the leakage detection switch.

The leakage protection circuit proposed according to the embodiment of the present disclosure detects the input voltage of the power supply through a voltage detection unit to generate a voltage detection signal. In this way, the drive unit can determine the type of the input voltage of the power supply based on the voltage detection signal, so that the threshold generation unit can generate a leakage protection threshold based on the type of the input voltage. Therefore, the leakage protection unit can control the load to be in a disconnected state based on the leakage protection threshold and the operation current of the leakage detection switch, achieving fast and effective leakage detection protection function. Therefore, the present disclosure can perform corresponding leakage detection and protection by detecting different type of the input voltages, which not only expands the disclosure scenarios, but also generates corresponding leakage protection thresholds for different type of the input voltages, reduces the risk of leakage failure or false detection caused by changes in input voltage, and ensures the accuracy and reliability of leakage protection under different voltage input conditions, fully meeting users' needs for safe electricity use

Optionally, in some embodiments of the present disclosure, the threshold generation unit is further configured to generate a first leakage protection threshold based on the input voltage of the power supply when the input voltage is DC voltage.

Optionally, in some embodiments of the present disclosure, the magnitude of the first leakage protection threshold is positively correlated with the magnitude of the DC voltage.

Optionally, in some embodiments of the present disclosure, the threshold generation unit comprises: a sampling holder which is configured to maintain the voltage detection signal based on a DC power supply flag signal to obtain sample-and-hold value wherein the DC power supply flag signal is obtained according to the type of input voltage; a multiplier, which is configured to multiply the sample-and-hold value by a preset coefficient to obtain a voltage adjustment value; an adder, which is configured to add a preset margin to the voltage adjustment value to obtain the first leakage protection threshold.

The embodiment of the present disclosure generates a first leakage protection threshold that is positively correlated with the supply voltage of the DC power supply when the input voltage is DC voltage. Since the first leakage protection threshold changes dynamically based on the supply voltage of the DC power supply, accurate and effective leakage protection can be achieved even if the variation range of the supply voltage is large, thereby improving the reliability and applicability of the leakage protection circuit.

Optionally, in some embodiments of the present disclosure, the threshold generation unit is further configured to generate a preset second leakage protection threshold when the input voltage is AC voltage.

Optionally, in some embodiments of the present disclosure, the threshold generation unit further comprises: a selector, which is configured to select one of the first and second leakage protection thresholds as the leakage protection threshold according to the type of the input voltage, and provide it to the leakage protection unit.

The embodiments of the present disclosure implement the selection of leakage protection thresholds by a selector, and select different leakage protection thresholds for different type of the input voltages. This enables the leakage protection circuit proposed in the present disclosure to be compatible with both AC and DC power inputs, while ensuring that the leakage protection circuit selects appropriate and accurate leakage protection thresholds under different voltage input conditions, thereby improving the accuracy and reliability of leakage detection.

Optionally, in some embodiments of the present disclosure, the leakage detection switch is set on a bus path between the power supply and the load, or the leakage detection switch is set between a node of the bus path between the power supply and the load and the ground terminal.

Optionally, in some embodiments of the present disclosure, the leakage protection unit comprises: a current detection resistor, is connected in series with the leakage detection switch and has a first node; a first comparator, is configured to compare the leakage detection value with the leakage protection threshold to output a first comparison signal, wherein the leakage detection value is used to denote the operation current of the leakage detection switch; a controller, which is configured to control the load to be in an off state if it is determined that a leakage is occurred based on the first comparison signal.

Optionally, in some embodiments of the present disclosure, the controller is further configured to determine the presence of leakage when the leakage detection value is determined to be less than the leakage protection threshold based on the first comparison signal.

The embodiments of this disclosure perform real-time monitoring on the operating current flowing through the leakage detection switch by a current sensing resistor, and input the real-time monitored leakage detection value into a first comparator to compare it with the leakage protection threshold. Once the leakage detection value is less than the leakage protection threshold, it is determined that a leakage is occurred, and the load is quickly disconnected through a controller. Therefore, this disclosure helps to identify leakage situations in a timely and accurate manner, improving the real-time response speed of leakage protection to prevent potential safety hazards caused by electrical equipment leakage.

Optionally, in some embodiments of the present disclosure, the controller is further configured to determine that the leakage is not occurred when the number of times the leakage detection value is determined to be greater than or equal to the leakage protection threshold based on the first comparison signal reaches a preset number of times.

In the embodiments of this disclosure, it is determined that the leakage is not occurred only when the number of times the leakage detection value is greater than or equal to the leakage protection threshold reaches a preset number. By setting multiple judgment logics, it is ensured that only when the leakage detection value is stably greater than or equal to the leakage protection threshold, it is judged that the leakage is not occurred. This effectively reduces the possibility of misjudgment caused by interference factors such as short-term current fluctuations. While ensuring the leakage protection effect, it avoids unnecessary frequent on-off control of the load by the controller, thereby improving the accuracy and anti-interference ability of leakage protection.

Optionally, in some embodiments of the present disclosure, the controller is further configured to control the connection between the load and the power supply when the leakage is not occurred, and drive the leakage detection switch to stop operation by the drive unit.

The embodiment of this disclosure sets the leakage detection switch to stop operation when the leakage is not occurred, in order to reduce the power consumption of the leakage protection circuit and help avoid the device aging problem caused by the long-term operation of the leakage detection switch.

Optionally, in some embodiments of the present disclosure, the drive unit comprises: a voltage type judgment module, which is configured to judge the type of the input voltage of the power supply according to the voltage detection signal, and send the judgment result to the threshold generation unit; a first pulse generation module, which is configured to generate a first detection pulse signal when the input voltage is a DC voltage; a second pulse generation module, which is configured to generate a second detection pulse signal when the input voltage is an AC voltage; a drive module, which is configured to drive the leakage detection switch to operate based on one of the first detection pulse signal and the second detection pulse signal.

Optionally, in some embodiments of the present disclosure, the voltage type judgment module comprises: a second comparator, which is configured to compare the voltage detection signal with a first reference voltage signal to output a second comparison signal, wherein the second comparison signal is used to determine whether the input voltage is a DC power voltage; a third comparator, which is configured to compare the voltage detection signal with a second reference voltage signal, to output a third comparison signal, wherein the third comparison signal is used to determine whether the input voltage is an AC voltage.

The present disclosure, by the second and third comparators within the voltage type judgment module, compares the voltage detection signal with the corresponding reference voltage signal, thereby achieving the judgment of the type of the input voltage at the power supply. Consequently, different detection pulse signals are generated to drive the leakage detection switch to operate according to different type of the input voltages. Therefore, this disclosure achieves the judgment of type of the input voltages by setting up the second and third comparators, thus enhancing the compatibility of the leakage protection circuit with different type of the input voltages.

Optionally, in some embodiments of the present disclosure, one of the first detection pulse signal and the second detection pulse signal is used to control the leakage detection switch to turn on and off intermittently.

This disclosure, by controlling the intermittent on and off of the leakage detection switch, achieves the judgement of leakage each time the leakage detection switch is turned on, and determines multiple and consecutively whether a leakage is occurred by intermittently turning the switch on and off, thereby improving the accuracy of leakage protection and reducing the possibility of false leakage judgments.

In the second aspect, embodiments of the present disclosure provide an electrical equipment, comprising: a load; a controllable for controlling whether the load is disconnected; the leakage protection circuit according to the above embodiments of the first aspect, the leakage protection circuit is configured to control the controllable switch to disconnect such that the load is in a disconnected state, when it is determined that the electrical equipment has leakage.

the electrical equipment proposed according to the embodiments of this disclosure realizes effective leakage detection under different type of the input voltages through a leakage protection circuit. In the event of leakage, the controllable switch is controlled to disconnect, so that the load is in an off state, thereby achieving a rapid and effective leakage protection function. Therefore, the present disclosure can perform corresponding leakage detection and protection by detecting different type of the input voltages. This not only expands the application scenarios, but also generates corresponding leakage protection thresholds for different type of the input voltages, reducing the risk of leakage failure or false detection due to changes in input voltage. This ensures the accuracy and reliability of leakage protection under different voltage input conditions, fully meeting user' needs for safe electricity use.

In a third aspect, embodiments of the present disclosure a leakage protection method, applied to the leakage protection circuit of above embodiments of the first aspect, and the method comprises: detecting the input voltage of the power supply to generate a voltage detection signal; determining the type of the input voltage of the power supply based on the voltage detection signal, and driving the leakage detection switch to operate; detecting the operation current flowing through the leakage detection switch, and controlling the load to be in a disconnected state if it is determined that a leakage is occurred based on the leakage protection threshold and the operation current of the leakage detection switch, wherein the leakage protection threshold is generated according to the type of input voltage.

According to the leakage protection method proposed in the embodiments of this disclosure, a voltage detection signal is generated by detecting the input voltage at the power supply, and the type of input voltage at the power supply is determined based on the voltage detection signal, and a leakage protection threshold is generated based on the type of input voltage, thus allowing the load to be controlled in an off state when leakage is detected based on the leakage protection threshold and the operating current of the leakage detection switch, thereby achieving a rapid and effective leakage detection and protection function. Therefore, this disclosure can perform corresponding leakage detection and protection by detecting different types of input voltages. This not only expands the disclosure scenarios, but also generates corresponding leakage protection thresholds for different types of input voltages, reducing the risk of leakage failure or false detection due to changes in input voltage. This ensures the accuracy and reliability of leakage protection under different voltage input conditions, fully meeting users' needs for safe electricity use.

### BRIEF DESCRIPTION OF THE DRAWINGS

To illustrate the specific embodiments of this disclosure or the technical solutions in the prior art more clearly, the following will briefly introduce the accompanying drawings required for the description of specific embodiments or prior art. Obviously, the accompanying drawings described below are some embodiments of this disclosure. For those of ordinary skill in the art, other accompanying drawings can be obtained based on these accompanying drawings without creative effort.

FIG. 1A is a circuit structure schematic view of the leakage protection circuit proposed in an embodiment of the present disclosure;

FIG. 1B is a circuit structure schematic view of the leakage protection circuit proposed in another embodiment of the present disclosure;

FIG. 2 is a circuit structure schematic view of the drive unit proposed in an embodiment of the present disclosure;

FIG. 3 is circuit structure schematic view of the threshold generation unit proposed in an embodiment of the present disclosure;

FIG. 4 is a circuit structure schematic view of the leakage protection unit proposed in an embodiment of the present disclosure;

FIG. 5 is a circuit structure schematic view of the drive module proposed in an embodiment of the present disclosure;

FIG. 6 is a signal waveform schematic view of the leakage protection circuit in an embodiment proposed in this disclosure;

FIG. 7 is another signal waveform schematic view of the leakage protection circuit in an embodiment proposed in this disclosure;

FIG. 8 is a signal waveform schematic view of the leakage protection circuit in another embodiment proposed in this disclosure;

FIG. 9 is another signal waveform schematic view of the leakage protection circuit in another embodiment proposed in this disclosure;

FIG. 10 is a structure schematic view of the electrical equipment proposed in an embodiment of the present disclosure;

FIG. 11 is a flowchart of the leakage protection method proposed in an embodiment of the present disclosure.

### DETAILED DESCRIPTION OF THE DISCLOSURE

The following will describe the preferred embodiments of the present disclosure in great details by combining with the accompanying drawings. However, the present invention is not restricted to these embodiments. The present disclosure convers any replacement, modifications, equivalent methods, and solutions made within the sprits and scope of the present disclosure.

To clarify the objectives, technical solutions, and advantages of the embodiments of this disclosure, the technical solutions in these embodiments will be described clearly and comprehensively below in conjunction with the accompanying drawings. Obviously, the described embodiments are a part of the embodiments of this disclosure, not all of them. Based on the embodiments in this disclosure, those of ordinary skill in the art can obtain all other embodiments falling within the protection scope of this disclosure without creative effort.

In relevant leakage detection and protection technologies, a transistor is usually incorporated into the circuit. The presence of leakage is determined by detecting the current flowing through the transistor. In the event of leakage, the load is directly disconnected to achieve leakage protection.

However, as users' demands for safe use of electrical equipment continue to rise, electrical equipment is becoming more and more intelligent. In some application scenarios, the leakage detection and protection function in related technologies cannot effectively achieve protection, greatly reducing the accuracy of leakage protection. This fails to meet the demands of increasingly intelligent electrical equipment and the safety requirements of users for the electrical system.

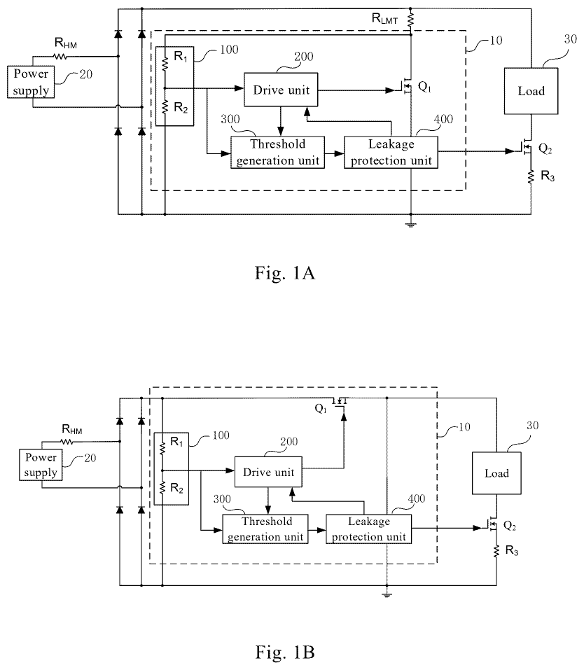

Embodiments of the present disclosure provide a leakage protection circuit 10, as shown in FIG. 1A or FIG. 1B. The leakage protection circuit 10 can be used in electrical equipments with load 30 of lighting, such as light-emitting diodes. By accurately identifying different power supply types, it can achieve leakage detection and protection for different electrical equipments. This not only expands the application scenarios, but also generates corresponding leakage protection thresholds for different type of the input voltages, reducing the risk of leakage failure or false detection due to changes in input voltage. This ensures the accuracy and reliability of leakage protection under different voltage input conditions, fully meeting users' needs for safe electricity use.

As shown in FIG. 1A or FIG. 1B, the leakage protection circuit 10 comprises: a leakage detection switch Q₁, a voltage detection unit 100, a drive unit 200, a threshold generation unit 300, and a leakage protection unit 400.

The leakage detection switch Q₁ is set between the power supply 20 and the load 30. For example, in some embodiments of the present disclosure, the leakage detection switch Q₁ can be set between a node of the bus path between the power supply and the load and the ground terminal, as shown in FIG. 1A; in some other embodiments of the present disclosure, the leakage detection switch Q₁ can also be set on the bus path between the power supply and the load, as shown in FIG. 1B. The present disclosure does not impose specific restriction on this, as long as the arrangement of the leakage detection switch can provide conditions for leakage current detection.

The voltage detection unit 100 is configured to detect the input voltage of the power supply 20 to generate a voltage detection signal. The drive unit 200 is configured to determine the type of input voltage of the power supply 20 based on the voltage detection signal, and drive the leakage detection switch Q₁ to operate. The threshold generation unit 300 is configured to generate a leakage protection threshold based on the type of input voltage. The leakage protection unit 400 is configured to detect the operation current flowing through the leakage detection switch Q₁ and control the load 30 to be in an off state if it is determined that a leakage is occurred based on the leakage protection threshold and the operation current of the leakage detection switch Q₁.

The leakage protection circuit provided in this embodiment detects the input voltage of the power supply 20 through the voltage detection unit 100, generates a voltage detection signal, and provides the voltage detection signal to the drive unit 200 to determine the type of input voltage of the power supply, thereby driving the leakage detection switch Q₁ to operate; meanwhile, the threshold generation unit 300 generates a corresponding leakage protection threshold based on the type of input voltage, and provides this leakage protection threshold along with the operation current flowing through the leakage detection switch to the leakage protection unit 400. This allows the leakage protection unit 400 to determine whether a leakage is occurred based on the aforementioned leakage protection threshold and operation current. In the event of leakage, it promptly and accurately controls the load 30 to disconnect, thereby reducing the electrical safety risks caused by the leakage and achieving rapid and effective leakage protection.

In summary, this disclosure can detect different types of input voltages for corresponding leakage protection, greatly enhancing the compatibility of the leakage protection circuit with various type of the input voltages and expanding its application scenarios. Furthermore, this disclosure can generate corresponding leakage protection thresholds for different types of input voltages, reducing the risk of leakage failure or false detection due to changes in input voltage, thereby ensuring the accuracy and reliability of leakage protection under different voltage input conditions.

It should be noted that in the circuit structure shown in FIG. 1A or FIG. 1B, the power supply 20 is used to supply load 30 with power, and the power supply 20 can be an AC power supply or a DC power supply. Wherein, the resistor RLMT shown in FIG. 1A is a current limiting resistor, and the resistor R_{HM} shown in FIG. 1A or FIG. 1B is the resistance value of the human body connected to the line in the presence of leakage. In addition, the load 30 is connected and disconnected in the line by setting the transistor Q₂. For example, in some examples of this disclosure, the gate of the transistor Q₂ is connected to the output terminal of the leakage protection unit 400, the drain of the transistor Q₂ is connected to the load 30, and the source of the transistor Q₂ is grounded through the current limiting resistor R3.

Wherein, in the leakage protection circuit shown in FIG. 1A, the leakage detection switch Q₁ is set between the node of the bus path between the power supply 20 and the load 30, and the ground terminal. In the leakage protection circuit illustrated in FIG. 1B, the leakage detection switch Q₁ can also be set on the bus path between the power supply and the load, to detect current variations between the power supply 20 and the load 30, thereby determining the presence of leakage based on the current changes.

As shown in FIG. 1A or FIG. 1B, the voltage detection unit 100 is connected to the power supply 20. The voltage detection unit 100 comprises a sampling resistor R₁ and a sampling resistor R₂, which are connected in series to form a voltage divider circuit, and a voltage detection signal is output at the connection node of the sampling resistor R₁ and the sampling resistor R₂. This voltage detection signal can represent the input voltage of the power supply 20, thereby allowing the type of input voltage to be determined using this voltage detection signal.

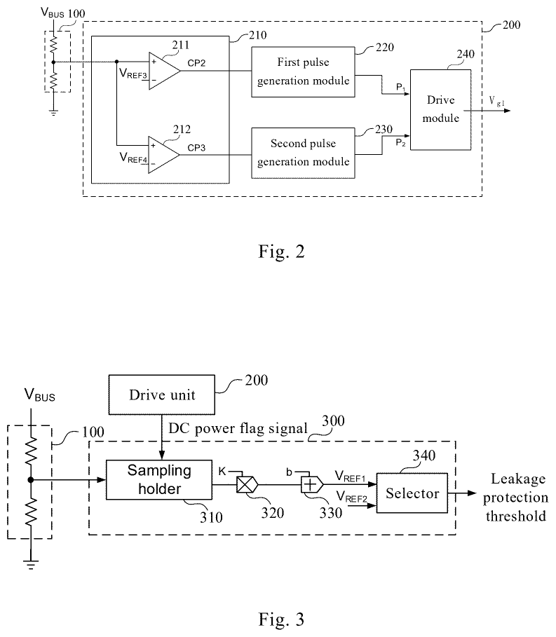

In some embodiments of the present disclosure, the drive unit 200 drives the leakage detection switch Q₁ to turn on and off according to the type of input voltage, so that the leakage protection unit 400 can determine whether a leakage is occurred based on the operation current flowing through the leakage detection switch Q₁ each time it is turned on. As shown in FIG. 2, the drive unit 200 comprises a voltage type judgment module 210, a first pulse generation module 220, a second pulse generation module 230, and a drive module 240.

Wherein, the voltage type judgment module 210 is configured to determine the type of the input voltage of the power supply 20 based on the voltage detection signal, and send the judgment result to the threshold generation unit 300.

Further, as shown in FIG. 2, the voltage type judgement module 210 comprises a second comparator 211 and a third comparator 212.

Wherein, the second comparator 211 is configured to compare the voltage detection signal with the first reference voltage signal V_{REF3}, and output a second comparison signal CP2. Specifically, the voltage detection signal can be input to the positive input terminal of the second comparator 211, and the first reference voltage signal V_{REF3} can be input to the negative input terminal of the second comparator 211. The second comparator 211 outputs the second comparison signal CP2 by comparing the magnitude between the voltage detection signal and the first reference voltage signal V_{REF3}. Thus it can be obtained that the second comparison signal CP2 can be used to determine whether the input voltage is a DC voltage.

The third comparator 212 is configured to compare the voltage detection signal with the second reference voltage signal V_{REF4}, to output a third comparison signal CP3. Specifically, the voltage detection signal is input to the positive input terminal of the third comparator 212, and the second reference voltage signal V_{REF4} is input to the negative input terminal of the third comparator 212. The third comparator 212 outputs the third comparison signal CP3 by comparing the magnitude between the voltage detection signal and the second reference voltage signal V_{REF4}. Thus, it can be concluded that this third comparison signal CP3 can be used to determine whether the input voltage is an AC voltage.

The first pulse generation module 220 is configured to generate a first detection pulse signal P₁ when the input voltage is DC voltage. The second pulse generation module 230 is configured to generate a second detection pulse signal P₂ when the input voltage is AC voltage. The drive module 240 is configured to drive the leakage detection switch Q₁ to operate based on one of the first detection pulse signal and the second detection pulse signal.

In some embodiments of the present disclosure, as shown in FIG. 1A, when the leakage detection switch Q₁ is set between the node of the bus path between the power supply and the load and the ground terminal, one of the first detection pulse signal P₁ and the second detection pulse signal P₂ is used to control the intermittent conduction and disconnection of the leakage detection switch Q₁. In other embodiments of the present disclosure, as shown in FIG. 1B, when the leakage detection switch Q₁ is set on the bus path between the power supply and the load, one of the first detection pulse signal P₁ and the second detection pulse signal P₂ is used to control the conduction of the leakage detection switch Q₁.

Specifically, if the input voltage is DC voltage, the first pulse generation module 220 will hold the received second comparison signal CP2 generated by the above second comparator 211 always at a high level. After a delay of time T_{DC}, the first pulse generation module 220 responds to the second comparison signal CP2 and generates the first detection pulse signal P₁, which is input to the drive module 240. The drive module 240 generates the drive signal Vg1 to drive the leakage detection switch Q₁ to turn on under the trigger of the first detection pulse signal P₁. It should be noted that in some embodiments of the present disclosure, the drive module 240 generates the drive signal V_{g1} under the trigger of the rising edge of the first detection pulse signal P₁. In other embodiments of the present disclosure, the drive module 240 can also generate the drive signal V_{g1} under the trigger of the falling edge of the first detection pulse signal P₁. In addition, when the leakage detection switch Q₁ can be set between the node of the bus path between the power supply and the load and the ground terminal, the above drive signal V_{g1} is a pulse signal, and there is a time interval Td₁ between every two adjacent pulses of the drive signals V_{g1}, that is, the leakage detection switch Q₁ is controlled to turn on once every other time interval Td₁, so as to control the leakage detection switch Q₁ to turn on and off intermittently. When the leakage detection switch Q₁ is set on the bus path between the power supply and the load, the above drive signal V_{g1} is a continuous signal, so as to control the leakage detection switch Q₁ to turn on.

If the type of the input voltage is AC voltage, due to the periodic fluctuation of the AC voltage, the second pulse generation module 230 will make the periodically received third comparison signal CP3 generated by the aforementioned third comparator 212 at high level, and generate the second detection pulse signal P₂ in response to the third comparison signal CP3 and input it to the drive module 240. The drive module 240 generates the drive signal V_{g1} to drive the leakage detection switch Q₁ to turn on under the trigger of the second detection pulse signal P₂. It should be noted that in some embodiments of the present disclosure, the drive module 240 generates the drive signal V_{g1} under the trigger of the rising edge of the second detection pulse signal P₂. In other embodiments of the present disclosure, the driving module 240 can also generate the driving signal V_{g1} under the trigger of the falling edge of the second detection pulse signal P₂. Additionally, when the leakage detection switch Q₁ can be set between the node of the bus path between the power supply and the load and the ground terminal, the above driving signal V_{g1} is a pulse signal, and there is a time interval Td₂ between every two adjacent pulses of the driving signal V_{g1}, that is, the leakage detection switch Q₁ is controlled to turn on once every other time interval Td₂, so as to control the leakage detection switch Q₁ to turn on and off intermittently. When the leakage detection switch Q₁ is set on the bus path between the power supply and the load, the above driving signal V_{g1} is a continuous signal, so as to control the leakage detection switch Q₁ to turn on.

This disclosure utilizes the second comparator 211 and the third comparator 212 in the voltage type judgment module 210 to compare the voltage detection signal with the corresponding reference voltage signal, so as to implement the determination of the type of the input voltage at the power supply 20. Consequently, different detection pulse signals are generated for various type of the input voltages to drive the leakage detection switch Q₁ to operate. Therefore, the embodiment of this disclosure achieves the judgment of type of the input voltages by setting up the second comparator 211 and the third comparator 212, so as to improve the compatibility of the leakage protection circuit 10 with different type of the input voltages. Furthermore, the judgment circuit is simple, reliable, and cost-effective.

In some embodiments of the present disclosure, the threshold generation unit 300 generates different leakage protection thresholds corresponding to different type of the input voltages, thereby ensuring accurate and effective leakage protection regardless of whether the power supply 20 is an AC power supply or a DC power supply.

Specifically, the threshold generation unit 300 is configured to generate the first leakage protection threshold V_{REF1} based on the input voltage of the power supply 20 when the input voltage is DC voltage.

Furthermore, in some embodiments of the present disclosure, the magnitude of the aforementioned first leakage protection threshold V_{REF1} is positively correlated with the supply voltage of the DC power supply.

As shown in FIG. 3, for the case where the type of the input voltage is DC power supply, the threshold generation unit 300 comprises: a sampling holder 310, a multiplier 320, and an adder 330, wherein the sampling holder 310 is configured to hold the voltage detection signal based on the DC power supply flag signal to obtain a sample-and-hold value. The multiplier 320 is configured to multiply the sample-and-hold value by a preset coefficient to obtain a voltage adjustment value. The adder 330 is configured to add the voltage adjustment value to a preset margin to obtain the first leakage protection threshold V_{REF1}.

As can be seen from the circuit structure shown in FIG. 3, the voltage detection signal generated by the voltage detection unit 100 is sampled and held by the sampling holder 310 to obtain a sample-and-hold value VHOLD. In addition, after determining that the type of the input voltage is DC voltage, the drive unit 200 will generate a DC power flag signal and input it to the sampling holder 310. Upon receiving the DC power flag signal, the sampling holder 310 inputs the sample-and-hold value VHOLD to the multiplier 320, so that the multiplier 320 multiplies the sample-and-hold value VHOLD by a preset coefficient k to obtain a voltage adjustment value. Then, the voltage adjustment value is added to a preset margin b by the adder 330, that is, the first leakage protection threshold V_{REF1} is determined by the following formula (1)

$${V}_{REF 1} = k * VHOLD + b \qquad ( 1 )$$

In the embodiment of the present disclosure, for the situation where the input voltage is DC voltage, a first leakage protection threshold V_{REF1} that is positively correlated with the supply voltage of the DC power supply is generated. Since the first leakage protection threshold V_{REF1} varies dynamically with the supply voltage of the DC power supply, it can generate an accurate leakage protection threshold even if the variation range of the supply voltage is large. Therefore, the leakage protection circuit 10 proposed in this disclosure can ensure the normal operation of the leakage protection function within a wide range of DC voltage inputs, improve the reliability and adaptability of the leakage protection circuit and fully meet the wide-range power supply requirements of electrical equipment.

In some embodiments of the present disclosure, the threshold generation unit 300 is further configured to generate a preset second leakage protection threshold V_{REF2} when the input voltage is AC voltage.

As can be seen from FIG. 1A or FIG. 1B, in the absence of leakage, when the human body is not connected to the circuit, the voltage across the current detection resistor R_{S} in the leakage protection unit 400 is determined by the following formula (2):

$${V}_{RS \_ H} = {I}_{DET} * {R}_{S} = {V}_{BUS} / ( {R}_{LMT} + {R}_{DSON} + {R}_{S} ) * {R}_{S} \qquad ( 2 )$$

In the formula, V_{RS_H} represents the voltage across the current detection resistor R_{S} in the absence of leakage. I_{DET} denotes the operation current flowing through the leakage detection switch Q₁. V_{BUS} signifies the bus voltage rectified and outputted by the power supply 20. The resistance of R_{LMT} can be set to zero, while RDSON stands for the on-resistance of the leakage detection switch Q₁. In scenarios where a leakage exists, and a human body is connected to the circuit, the voltage across the current detection resistor R_{S} in the leakage protection unit 400 is determined by the following formula (3):

$${V}_{RS \_ L} = {I}_{DET} * {R}_{S} = {V}_{BUS} / ( {R}_{HM} + {R}_{LMT} + {R}_{DSON} + {R}_{S} ) * {R}_{S} \qquad ( 3 )$$

In the formula, V_{RS_L}, represents the voltage across the current detection resistor R_{S} in the presence of leakage, and R_{HM} denotes the resistance value of the human body connected to the circuit, which is equivalent to 5000.

In some embodiments of the present disclosure, the value of the above second leakage protection threshold V_{REF2} may fall between V_{RS_L}, and V_{RS_H}, that is, V_{RS_L}<V_{REF2}<V_{RS_H}. By reasonably setting the value of the second leakage protection threshold V_{REF2}, accurate and effective leakage protection can be achieved when the power supply 20 is an AC power supply.

It can be seen that the first leakage protection threshold V_{REF1} generated for DC power supply is a threshold that dynamically changes based on the input voltage, while the second leakage protection threshold generated for AC power supply is a static threshold. For electrical equipment with load 30, the input voltage of the AC power supply can be a periodically varying 220V mains supply, with relatively stable amplitude changes. However, in the case of DC power supply as the voltage input type, the amplitude changes of its input voltage are unstable. For example, for different operation states of the electrical equipment and different loads, the DC power supply can input input voltages with different amplitude values. Therefore, if a leakage is occurred, the amplitude of the leakage current corresponding to the AC power supply also varies periodically within a foreseeable range. Compared with the DC power supply, the amplitude of the leakage current corresponding to the AC power supply is relatively fixed. Therefore, a static second leakage protection threshold can be set. For the case where the type of the input voltage is a DC power supply, a dynamic first leakage protection threshold which is positively correlated with the supply voltage of the DC power supply can be set.

Therefore, the present disclosure performs corresponding leakage detection protection by detecting types of different input voltages, which not only expands the application scenarios, but also generates corresponding leakage protection thresholds for different type of the input voltages, reducing the risk of leakage failure or false detection caused by changes in input voltage, ensuring the accuracy and reliability of leakage protection under different voltage input conditions, and fully meeting the users' needs for safe electricity use.

As shown in FIG. 3, the above threshold generation unit 300 further comprises a selector 340, which is configured to select one of the first leakage protection threshold V_{REF1} and the second leakage protection threshold V_{REF2} as the leakage protection threshold according to the type of the input voltage, and provide it to the leakage protection unit 400. In some embodiments of the present disclosure, the selector 340 is a data selector MUX, which is connected to the driving unit 200 to receive the judgment result of the type of the input voltage, and then select one of the first leakage protection threshold V_{REF1} and the second leakage protection threshold V_{REF2} based on the judgment result to input into the leakage protection unit 400.

Embodiments of the present disclosure, by the selection of leakage protection threshold through a selector MUX, select different leakage protection thresholds for different type of the input voltages, which enables the leakage protection circuit proposed in this disclosure to be compatible with both AC and DC power inputs, while ensuring that the leakage protection circuit selects appropriate and accurate leakage protection thresholds for different voltage input conditions, thereby improving the accuracy and reliability of leakage detection.

After determining the leakage protection threshold corresponding to the type of the input voltage, embodiments of this disclosure compare the operation current flowing through the leakage detection switch 100 with the determined leakage protection threshold through the leakage protection unit 400 to determine whether a leakage is occurred.

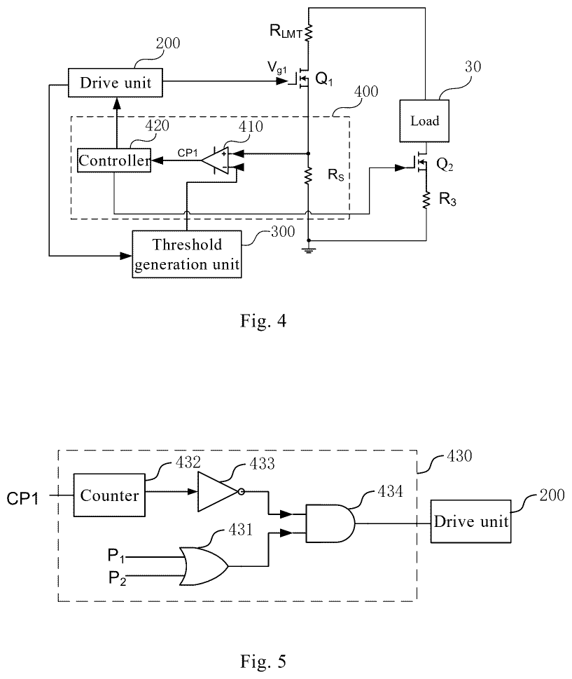

Specifically, in some embodiments of the present disclosure, as shown in FIG. 4, the above leakage protection unit 400 comprises a current detection resistor R_{S}, a first comparator 410, and a controller 420. Wherein, the current detection resistor R_{S} is connected in series with the leakage detection switch Q₁ and has a first node. The positive input terminal of the first comparator 410 is connected to the first node, and the negative input terminal of the first comparator 410 is connected to the output terminal of the threshold generation unit 300. The first comparator 410 is configured to compare the leakage detection value with the leakage protection threshold to output the first comparison signal CP1, wherein the leakage detection value is used to characterize the operation current of the leakage detection switch Q₁. Controller 420 is configured to control load 30 to be in a disconnected state when leakage is determined based on the first comparison signal CP1.

Further, controller 420 is also configured to determine the presence of leakage when the leakage detection value is less than the leakage protection threshold based on the first comparison signal CP1.

Specifically, the operation current flowing through the leakage detection switch Q₁ is detected by the current detection resistor R_{S}, and the detected operation current is sent to the positive input terminal of the first comparator 410. In addition, the output terminal of the threshold generation unit 300 is connected to the negative input terminal of the first comparator 410 to send the leakage protection threshold output by the threshold generation unit 300 to the negative input terminal of the first comparator 410. When the operation current flowing through the leakage detection switch Q₁ is less than the leakage protection threshold, it is determined that a leakage is occurred and the first comparison signal CP1 is generated through the output terminal of the first comparator 410. The first comparison signal CP1 is sent to the controller 420, and the controller 420 controls the switch Q₂ to turn off, so as to control the load 30 to be in the disconnected state.

Embodiments of the present disclosure monitor the operation current flowing through the leakage detection switch Q₁ in real time through the current detection resistor R_{S}, and inputs the real-time monitored leakage detection value into the first comparator 410 to compare the leakage detection value with the leakage protection threshold. Once the leakage detection value is less than the leakage protection threshold, it is determined that a leakage is occurred, and the controller 420 quickly controls the load 30 to disconnect. Therefore, this disclosure helps to timely and accurately identify leakage situations, improves the real-time response speed of leakage protection, and prevents safety hazards caused by electrical equipment leakage.

In some embodiments of the present disclosure, the controller 420 is further configured to determine that the leakage is not occurred when the number of times that the leakage detection value is greater than or equal to the leakage protection threshold reaches a preset number of times based on the first comparison signal.

Furthermore, the controller 420 is further configured to control the connection between the load 30 and the power supply 20 in the absence of leakage, and to drive the leakage detection switch Q₁ to stop operation through the driving unit 200.

In order to achieve the above configuration of the controller 420, the present embodiment provides a counting logic circuit 430 as shown in FIG. 5 in the controller 420. Specifically, the counting logic circuit 430 comprises an OR gate 431, a counter 432, an inverter 433, and an AND gate 434.

In the counting logic circuit 430 shown in FIG. 5, the first detection pulse signal P₁ generated by the first pulse generation module 220 and the second detection pulse signal P₂ generated by the second pulse generation module 230 are respectively input into the OR gate 431, and the output terminal of the OR gate 431 is connected to the first input terminal of the AND gate 434. The first comparison signal CP1 generated by the first comparator 410 in the leakage protection unit 400 is input into the counter 432. The output terminal of the counter 432 is connected to the second input terminal of the AND gate 434 through an inverter 433, and the output terminal of the AND gate 434 is used to output the control signal that ultimately controls the on or off of the leakage detection switch Q₁.

Based on the above counting logic circuit, when the OR gate 431 receives one of the first detection pulse signal P₁ and the second detection pulse signal P₂, it outputs a high level to the first input terminal of the AND gate 434. Wherein, the number of times the leakage detection value is greater than or equal to the leakage protection threshold is recorded. If the number of times does not reach the preset number, the output terminal of the counter 432 outputs a low level, and after being inverted by the inverter 433, it is converted to a high level and sent to the second input terminal of the AND gate 434. The output terminal of the AND gate 434 outputs a high level and sends it to the driving unit 200. At this time, it will not affect the intermittent on and off process of the leakage detection switch Q₁ controlled by the driving unit 200.

If the number of times reaches the preset number of times, the output terminal of the counter 432 outputs a high level, and after being inverted by the inverter 433, it is converted to a low level and sent to the second input terminal of the AND gate 434. At this time, the output terminal of the AND gate 434 is low level and sent to the driving unit 200, which determines that the leakage is not occurred. When the leakage is not occurred, the leakage detection switch Q₁ is driven by the driving unit 200 to stop operation.

The embodiments of the disclosure control the leakage detection switch to stop operation in the absence of leakage, in order to reduce the power consumption of the leakage protection circuit and help avoid device aging caused by long-term operation of the leakage detection switch.

In addition, embodiments of the present disclosure, by setting the above multiple times of judgement logic, ensure that the leakage is not occurred only when the leakage detection value is stably greater than or equal to the leakage protection threshold, thereby effectively reducing the possibility of leakage misjudgment. On the premise of ensuring the effectiveness of leakage protection, it avoids the controller from frequently controlling the unnecessary connection and disconnection of the load, thereby improving the accuracy and anti-interference ability of leakage protection. For example, when a leakage is occurred, it is possible to detect a leakage detection value greater than or equal to the leakage protection threshold during a certain instantaneous current fluctuation. If the above multiple times of judgment logic is not set, the controller 420 will determine this accidental fluctuation situation as the absence of leakage and control the load 30 to be in the connected state. But then the instantaneous current fluctuation is eliminated, and next time the leakage detection value is detected to be less than the leakage protection threshold, the controller 420 will control the load 30 to be in a disconnected state. Thus it can be seen that in the case of occasional fluctuations in instantaneous current, if the above multiple times of judgment logic is not set, the controller 420 is prone to misjudging the absence of leakage, thereby erroneously controlling the load 30 to be in the connected state, causing frequent connection and disconnection of the load 30 in the line, which not only affects the user's experience in using electrical equipment, but also affects the device life.

Thus it can be seen that the configuration of the controller 420 in terms of multiple times of logical judgments can not only avoid the controller frequently controlling the unnecessary connection and disconnection of the load while ensuring the effectiveness of leakage protection, but also control the leakage detection switch to stop operation when the leakage is not occurred, thereby reducing the power consumption of the leakage protection circuit and helping to avoid device aging caused by long-term operation of the leakage detection switch.

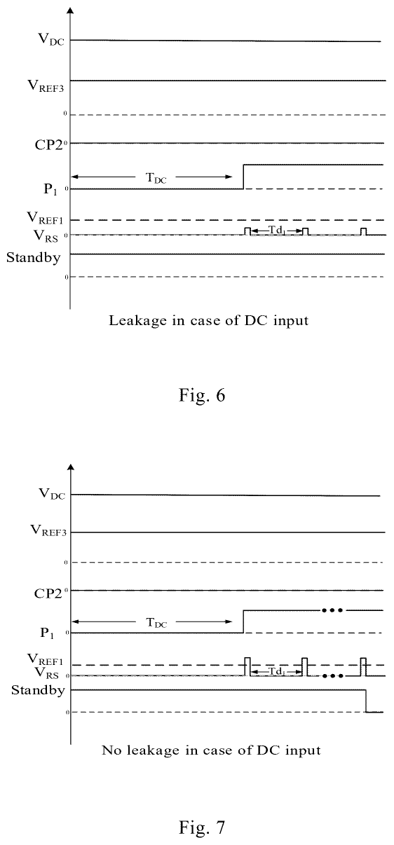

FIGS. 6 to 9 respectively show the signal waveform diagrams for leakage protection under two type of the input voltages: DC voltage and AC voltage. Specifically, as shown in FIGS. 6 and 7, the voltage detection signal V_{DC} is greater than the first reference voltage signal V_{REF3}. Therefore, the type of the input voltage is determined to be a DC voltage, and the second comparison signal CP2 is generated by the second comparator 211. The first pulse generation module 220 responds to the second comparison signal CP2 after a delay of T_{DC} and generates the first detection pulse signal P₁. The driving module 240 generates the driving signal V_{g1} that drives the leakage detection switch Q₁ to conduct under the trigger of the first detection pulse signal P₁, and there is a time interval T_{d1} between every two adjacent pulses of the driving signal V_{g1}. The operation current flowing through the leakage detection switch Q₁ is detected under each pulse of the driving signal V_{g1}, and the obtained leakage detection value V_{RS} is compared with the first leakage protection threshold V_{REF1}. As shown in FIG. 6, if the leakage detection value V_{RS} is less than the first leakage protection threshold V_{REF1}, it indicates that a human body is currently connected to the line, causing a high impedance of the line and a decrease in the operation current flowing through the leakage detection switch Q₁. Therefore, it is determined that a leakage is occurred. At this time, the Standby signal is set to a high level to keep the load 30 in the disconnected state. As shown in FIG. 7, if the leakage detection value V_{RS} is greater than the first leakage protection threshold V_{REF1}, it indicates that there is currently no human body connected to the line and the line impedance is small. Therefore, it is determined that the leakage is not occurred. At this time, the Standby signal is converted from high level to low level to keep the load 30 in the on state.

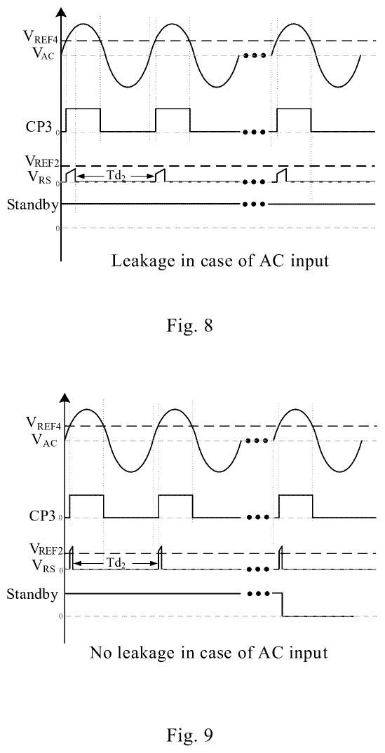

Similarly, as shown in FIGS. 8 and 9, when the voltage detection signal VAC is greater than the second reference voltage signal V_{REF4}, the input voltage is determined to be AC voltage, and the third comparator 212 generates the third comparison signal CP3. The second pulse generation module 230 responds to the third comparison signal CP3 and generates the second detection pulse signal P₂. The driving module 240 generates the driving signal V_{g1} that drives the leakage detection switch Q₁ to conduct under the trigger of the second detection pulse signal P₂, and there is a time interval Td₂ between every two adjacent pulses of the driving signals V_{g1}. The operation current flowing through the leakage detection switch Q₁ is detected under each pulse of the driving signal V_{g1}, and the obtained leakage detection value V_{RS} is compared with the second leakage protection threshold V_{REF2}. As shown in FIG. 8, if the leakage detection value V_{RS} is less than the second leakage protection threshold V_{REF2}, it indicates that a human body is currently connected to the line, causing a large impedance in the line and a decrease in the working current flowing through the leakage detection switch Q₁. Therefore, it is determined that a leakage is occurred. At this time, the Standby signal is set to a high level to keep the load 30 in the disconnected state. As shown in FIG. 9, if the leakage detection value V_{RS} is greater than the second leakage protection threshold V_{REF2}, it indicates that there is currently no human body connected to the line, and the line impedance is small. Therefore, it is determined that the leakage is not occurred. At this time, the Standby signal is converted from high level to low level to keep the load 30 in the on state.

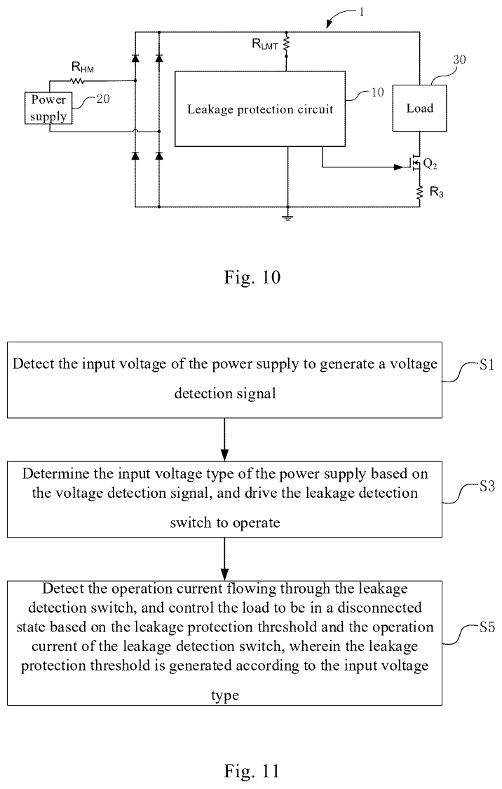

Correspondingly, refer to FIG. 10, embodiments of the disclosure provide an electrical equipment 1, which comprises a load 30, a controllable switch Q₂, and the leakage protection circuit 10 described in the above embodiments.

Wherein, the controllable switch Q₂ is used to control whether the load 30 is disconnected; the leakage protection circuit 10 is configured to control the controllable switch Q₂ to disconnect when it is determined that a leakage is occurred in the electrical equipment 1, so that the load 30 is in the disconnected state. Those skilled in the art know that controllable switches can also be controllable switches in the drive circuit that drives LEDs.

The electrical equipment proposed in this embodiment can achieve effective leakage detection under different type of the input voltages through a leakage protection circuit, and control the controllable switch to disconnect in the presence of leakage phenomenon, so as to keep the load in a disconnected state, thereby achieving fast and effective leakage protection function. Therefore, the electrical equipment proposed in the embodiments of the present disclosure performs corresponding leakage detection and protection by detecting different type of the input voltages, which not only expands the application scenarios, but also generates corresponding leakage protection thresholds for different type of the input voltages and reduces the risk of leakage failure or false detection caused by changes in input voltage, and ensures the accuracy and reliability of leakage protection under different voltage input conditions, fully meeting the users' needs s for safe electricity use.

The further functional descriptions of the above modules and units are the same as those in the corresponding embodiments, and will not be repeated here.

Correspondingly, refer to FIG. 11, embodiments of the present disclosure provide a leakage protection method, which is applied to the leakage protection circuit in the above embodiments. The method includes the following steps:

Step S1, detect the input voltage of the power supply to generate a voltage detection signal;

Step S3, determine the type of the input voltage of the power supply based on the voltage detection signal, and drive the leakage detection switch to operate;

Step S5, detect the operation current flowing through the leakage detection switch, and control the load to be in a disconnected state based on the leakage protection threshold and the operation current of the leakage detection switch, wherein the leakage protection threshold is generated according to the type of the input voltage.

The above leakage protection method proposed in this disclosure generates a voltage detection signal by detecting the input voltage of the power supply, determines the type of the input voltage of the power supply based on the voltage detection signal, and generates a leakage protection threshold based on the type of the input voltage. Therefore, it can control the load to be in a disconnected state based on the leakage protection threshold and the working current of the leakage detection switch, achieving fast and effective leakage detection protection function. Therefore, this present disclosure can perform corresponding leakage detection and protection by detecting different type of the input voltages, which not only expands the application scenarios, but also generates corresponding leakage protection thresholds for different type of the input voltages, reduces the risk of leakage failure or false detection caused by changes in input voltage, and ensures the accuracy and reliability of leakage protection under different voltage input conditions, fully meeting users' needs for safe electricity use.

The further functional descriptions of each method step mentioned above are the same as those in the above corresponding embodiments, and are omitted here.

It should be noted that the steps shown in the flowcharts can be executed in a computer system such as a set of computer executable instructions, and though the logical order is shown in the flowchart, in some cases, the steps shown or described may be executed in a different order than here.

Although the embodiments of the present disclosure have been described in conjunction with the accompanying drawings, those skilled in the art may make various modifications and variations without departing from the spirit and scope of the present disclosure, and such modifications and variations all fall in the scope defined by the appended claims.

For the convenience of description, the above devices are divided into various units in terms of function and described separately. Of course, the functions of each unit can be implemented in the same one or multiple software and/or hardware when implementing the present disclosure.

This disclosure is described with reference to the flowcharts and/or block diagrams of the method, device (system), and computer program product according to the embodiments of this disclosure. It should be understood that each process and/or block in the flowchart and/or block diagram, as well as the combination of processes and/or blocks in the flowchart and/or block diagram, can be implemented by computer program instructions. These computer program instructions can be provided to a processor of a general-purpose computer, specialized computer, embedded processor, or other programmable data processing device to generate a machine, such that the instructions executed by the processor of the computer or other programmable data processing device generate a device for implementing the functions specified in one or more processes in the flowchart and/or one or more boxes in the block diagram.

These computer program instructions can also be stored in computer-readable memory that can guide a computer or other programmable data processing device to operate in a specific manner, causing the instructions stored in the computer-readable memory to produce a manufactured product including instruction devices that implement the functions specified in a flowchart or multiple flowcharts and/or a block diagram or multiple blocks.

These computer program instructions can also be loaded onto a computer or other programmable data processing device, enabling a series of operational steps to be executed on the computer or other programmable device to generate computer implemented processing, thus the instructions executed on the computer or other programmable device provide steps for implementing the functions specified in one or more processes in the flowchart and/or one or more boxes in the block diagram.

It should also be noted that the terms “comprise”, “include” or any other variation thereof are intended to encompass non-exclusive inclusion, such that a process, method, good or equipment which includes a series of elements not only includes those elements, but also includes other elements not explicitly listed, or also includes elements inherent to such process, method, good or equipment. Without further limitations, the element defined by the statement “include one . . . ” does not exclude the existence of other identical elements in the process, method, product, or device that includes the element in question.

The various embodiments in this specification are described in a progressive manner, and the same and similar parts between each embodiment can be referred to each other. Each embodiment focuses on the differences from other embodiments. Especially, for the method implementation examples, due to their basic similarity to hardware circuit implementation examples, the description is relatively simple. For relevant information, please refer to the part of the description of the method implementation examples.

The above are only embodiments of the present disclosure and are not intended to limit the present disclosure. For those skilled in the art, this disclosure may have various modifications and variations. Any modifications, equivalent substitutions, improvements, etc. made within the spirit and principles of this disclosure shall be included within the scope of the claims of this disclosure.

Although the embodiments of the present disclosure have been described in conjunction with the accompanying drawings, those skilled in the art may make various modifications and variations without departing from the spirit and scope of the present disclosure, and such modifications and variations fall within the scope defined by the appended claims.

What is claimed is:

1. A leakage protection circuit, comprising:
a leakage detection switch set between a power supply and a load;
a voltage detection unit, configured to detect an input voltage of the power supply to generate a voltage detection signal;
a drive unit, configured to determine a type of the input voltage of the power supply based on the voltage detection signal, and drive the leakage detection switch to operate;
a threshold generation unit, configured to generate a leakage protection threshold based on the type of the input voltage; and
a leakage protection unit, configured to detect an operation current flowing through the leakage detection switch, and control the load to be in an off state if determining that a leakage is occurred based on the leakage protection threshold and the operation current of the leakage detection switch.

2. The leakage protection circuit of claim 1, wherein the threshold generation unit is further configured to generate a first leakage protection threshold based on the input voltage of the power supply when the input voltage is DC voltage.

3. The leakage protection circuit of claim 2, wherein a magnitude of the first leakage protection threshold is positively correlated with a magnitude of the DC voltage.

4. The leakage protection circuit of claim 3, wherein the threshold generation unit comprises:
a sampling holder, configured to maintain the voltage detection signal based on a DC power supply flag signal to obtain a sample-and-hold value wherein the DC power supply flag signal is obtained according to the type of the input voltage;
a multiplier, configured to multiply the sample-and-hold value by a preset coefficient to obtain a voltage adjustment value; and
an adder, configured to add a preset margin to the voltage adjustment value to obtain the first leakage protection threshold.

5. The leakage protection circuit of claim 2, wherein the threshold generation unit is further configured to generate a preset second leakage protection threshold when the input voltage is AC voltage.

6. The leakage protection circuit of claim 5, wherein the threshold generation unit further comprises:
a selector, configured to select one of the first leakage protection threshold and the second leakage protection threshold as the leakage protection threshold according to the type of the input voltage, and provide the leakage protection threshold to the leakage protection unit.

7. The leakage protection circuit of claim 1, wherein the leakage detection switch is set on a bus path between the power supply and the load, or the leakage detection switch is set between a node of the bus path between the power supply and the load and the ground terminal.

8. The leakage protection circuit of claim 1, wherein the leakage protection unit comprises:
a current detection resistor, being connected in series with the leakage detection switch and having a first node;
a first comparator, configured to compare the leakage detection value with the leakage protection threshold to output a first comparison signal, wherein the leakage detection value represents the operation current of the leakage detection switch;
a controller, configured to control the load to be in an off state if determining that the leakage is occurred based on the first comparison signal.

9. The leakage protection circuit of claim 8, wherein the controller is further configured to determine the leakage is occurred when the leakage detection value is determined to be less than the leakage protection threshold based on the first comparison signal.

10. The leakage protection circuit of claim 8, wherein the controller is further configured to determine that the leakage is not occurred when a number of times the leakage detection value is determined to be greater than or equal to the leakage protection threshold based on the first comparison signal reaches a preset number of times.

11. The leakage protection circuit of claim 10, wherein the controller is further configured to control connection between the load and the power supply when the leakage is not occurred, and drive the leakage detection switch to stop operation by the drive unit.

12. The leakage protection circuit of claim 1, wherein the drive unit comprises:
a voltage type judgment module, configured to judge the type of the input voltage of the power supply according to the voltage detection signal, and send the judgment result to the threshold generation unit;
a first pulse generation module, configured to generate a first detection pulse signal when the input voltage is a DC voltage;
a second pulse generation module, configured to generate a second detection pulse signal when the input voltage is an AC voltage;
a drive module, configured to drive the leakage detection switch to operate based on one of the first detection pulse signal and the second detection pulse signal.

13. The leakage protection circuit of claim 12, wherein the voltage type judgment module comprises:
a second comparator, configured to compare the voltage detection signal with a first reference voltage signal to output a second comparison signal, wherein the second comparison signal is used to determine whether the input voltage is a DC voltage;
a third comparator, configured to compare the voltage detection signal with a second reference voltage signal, to output a third comparison signal, wherein the third comparison signal is used to determine whether the input voltage is an AC voltage.

14. The leakage protection circuit of claim 12, wherein one of the first detection pulse signal and the second detection pulse signal is used to control the leakage detection switch to turn on and off intermittently.

15. An electrical equipment, wherein comprising:
a load;
a controllable switch for controlling whether the load is disconnected;
the leakage protection circuit of claim 1, configured to control the controllable switch to disconnect if determining that the leakage is occurred in the electrical equipment, such that the load is in a disconnected state.

16. The electrical equipment according to claim 15, wherein the controllable switch is a switch connected in series with the load, or a switch driving the drive circuit in the load.

17. A leakage protection method applied to the leakage protection circuit of claim 1, wherein the method comprises:
detecting the input voltage of the power supply to generate the voltage detection signal;
determining the type of the input voltage of the power supply based on the voltage detection signal, and driving the leakage detection switch to operate;
detecting the operation current flowing through the leakage detection switch, and controlling the load to be in a disconnected state if determining that a leakage is occurred based on the leakage protection threshold and the operation current of the leakage detection switch, wherein the leakage protection threshold is generated according to the type of the input voltage.
